(19) United States
(12) Patent Application Publication
(10) Pub. No.: US 2002/0075806 A1
(43) Pub. Date: Jun. 20, 2002

(54) Delivery of high QoS broadband services

(76) Inventors: Ofir Shalvi, Herzlia (IL); Noam Geri, Los Altos, CA (US)

Correspondence Address: TEXAS INSTRUMENTS INCORPORATED, P O BOX 655474, M/S 3999, DALLAS, TX, 75265

(21) Appl. No.: 09/995,140

(22) Filed: Nov. 27, 2001

Related U.S. Application Data
(60) Provisional application No. 60/253,155, filed on Nov. 27, 2000.

(51) Int. Cl. G01R 31/08; H04J 3/16

(52) U.S. Cl. 370/235; 370/468

(57) ABSTRACT

A data communication method and system are provided for preserving quality of service throughout the system. A data communication system is provided that comprises: a first manager for allocating a first time slot to a first network; and a second manager for allocating a second time slot to a second network such that one of the first time slot or the second time slot begins a short time before the other of the first time slot or the second time slot begins wherein data is transmitted between the second network and the first network during the first time slot or the second time slot. Other methods and systems are also provided.

### FIELD OF THE INVENTION

This invention generally relates to communication systems, and more specifically to systems and methods for data transmission.

### BACKGROUND OF THE INVENTION

Cable modems are being deployed today that allow high speed Internet access in the home over a cable network, often referred to as a hybrid fiber coax (HFC) cable network. The architecture of a typical cable modem used in a cable network is shown in FIG. 1. A cable modem 10 is a unit that is installed in the consumer or customer premises equipment (CPE) that may comprise a personal computer (PC) 13 or other computing device, for example. The cable modem (CM) 10 is adapted to communicate with the cable modem termination system (CMTS) that is typically located at a cable network provider's headend 12. The cable modem 10 is a modulator/demodulator that receives Internet traffic or information from a server through the headend 12 and puts it into a format recognizable by a user's PC 13, allowing a user to browse the Internet and send/receive e-mail just as they would with a conventional modem on a PC. Using a cable modem 10 over a cable network provides a much faster connection, being at least 50 times faster than a 56K modem, for example. Only one cable modem 10 is shown in FIG. 1. However, there are generally multiple cable modems 10 connected to a given headend 12.

Generally, cable modem 10 performs the modulation and demodulation and the operations necessary to interface with a user's PC. A cable modem 10 typically comprises a transmitter 14 for upstream modulation of a signal that is transmitted to a receiver 16 in the headend 12 that serves as an upstream demodulator. The upstream signal may comprise webpage selection or search information, for example, and may be a QPSK/16QAM modulated signal at 3 Mbits/sec. The cable modem 10 also comprises a receiver 18 for downstream demodulation of signals received from a transmitter 20 in the headend 12 that serves as a downstream modulator. The downstream modulation/demodulation may be 64QAM/256QAM at 27-56 Mbits/s, for example. Both the cable modem 10 and headend 12 include MACs 22, 24 that control the media access control (MAC) sublayer of the communication network.

A standard for communicating data over cable is the Data Over Cable Service Interface Specification (DOCSIS). There have been several iterations thus far of DOCSIS (e.g., 1.0, 1.1 and 2.0). According to the DOCSIS 1.0 specification, in the United States, the cable downstream channel which may be capable of carrying several Gigabits of data per second is divided into 6 MHz sub-channels that are capable of carrying 30-40 Megabits of data per second each from the cable headend 12 to the Cable Modems (CM's) 10.

The cable industry is realizing that home networking solutions are useful as they may assist in increasing operator revenues by facilitating distribution of data, voice, video, and multimedia services within the home beyond the PC. There are several home networking candidates: wireless solutions, phone-line solutions, power-line solutions, and solutions that are based on new wiring (e.g. Ethernet and IEEE1394). Of all these HN technologies, Wireless Home Networking (WHN) has the distinct advantage of allowing access to the network from any point in the home without requiring any wires at all, neither new nor old.

With DOCSIS technology now in place to solve the “last mile” challenge, the cable industry faces a new challenge—delivering broadband services through “the last 100 feet” from the perimeter of the home to the end-user. Home Networking (HN) standards and technologies are being developed to address this need. Home networks will connect a variety of home devices including PC's, PC peripherals, cellular devices, entertainment devices (such as TVs, Interactive Set-Top Boxes (STBs), Hi Fi systems and Play Stations), and home appliances. HN will drive and be driven by a wide range of applications such as:

Communications applications: e.g. fast Internet access from home devices (PC, TV, PDA), digital voice over cable, video streaming into the house;

Productivity applications: e.g. file sharing, printer sharing;

Entertainment application: e.g. video and audio streaming, video on demand, gaming;

Home control applications: e.g. remote control and remote maintenance of devices; and

Security applications: e.g. baby monitor, security camera.

The data traffic within the home will consist of a combination of internally generated data and external data from broadband services. Cable operators find themselves in a situation where the services that they provide to the home are distributed through a network over which they have limited control while competing for bandwidth with other sources of data that are also beyond the operators' control. In order to ensure that the users' experience of the broadband services is enhanced by the Home Network and not degraded, cable operators and vendors to the cable industry are working with the HN vendors to ensure that the HN solutions are suitable for distribution of broadband services. Some of the preferences of cable operators with respect to HN are high data rate, Quality of Service (QoS), reliable data rate and connectivity that will match the high reliability of the data service to the home and low cost. In addition, no new wires is preferable because installing new wires is a burden that few users will probably undertake. Many new homes are being designed with dedicated Home Networking wires in every room, but the vast majority of current homes will probably rely on either the use of existing wires or wireless solutions.

The Home Network preferably supports multiple Standard Definition TV (SDTV) MPEG II streams, voice streams, and data streams. It also is preferably scalable to support HDTV and video conferencing, which will probably become more popular in the future. A network with an effective data rate of 10 Mbps (Mega bits per second) is currently considered the bare minimum for supporting basic Internet service or a single SDTV stream together with voice service and other low bandwidth services. A 20 Mbps network will also allow, in addition, a couple of SDTV streams. However, to support the vision of the ‘broadband home’ in which bandwidth intensive HDTV signals are distributed within the home together with multiple streams of video from various sources, such as cable STBs, video hard-disk recorders, and video cameras, data rates of over 50 Mbps are preferable.

With HN playing an increasingly important role in the distribution of Broadband services by cable operators into the home, HN solutions will likely evolve to fit the operators needs.

### SUMMARY OF THE INVENTION

In general, and in a form of the present invention a system and method are provided which preserve high quality of service in a multi-network system. The present invention allows distribution of multiple data, voice, video, and multimedia streams, for example inside the home in an efficient manner without degrading quality of service.

In accordance with the present invention, a data communication system is disclosed that comprises a first manager for allocating a first time slot to a first network; and a second manager for allocating a second time slot to a second network such that one of the first time slot or the second time slot begins a short time before the other of the first time slot or the second time slot begins wherein data is transmitted between the second network and the first network during the first time slot or the second time slot. Other methods and systems are also disclosed.

### BRIEF DESCRIPTION OF THE DRAWINGS

Particular embodiments in accordance with the invention will now be described, by way of example only, and with reference to the accompanying drawings in which like reference signs are used to denote like parts and in which the Figures relate to the digital system of FIG. 1, unless otherwise stated, and in which:

FIG. 1 is a simplified architecture of a typical cable modem system;

FIG. 2 illustrates a CSMA network operation;

FIG. 3 illustrates a DOCSIS managed network operation; and

FIG. 4 illustrates an exemplary upstream Synchronized Managed Network operation according to the present invention.

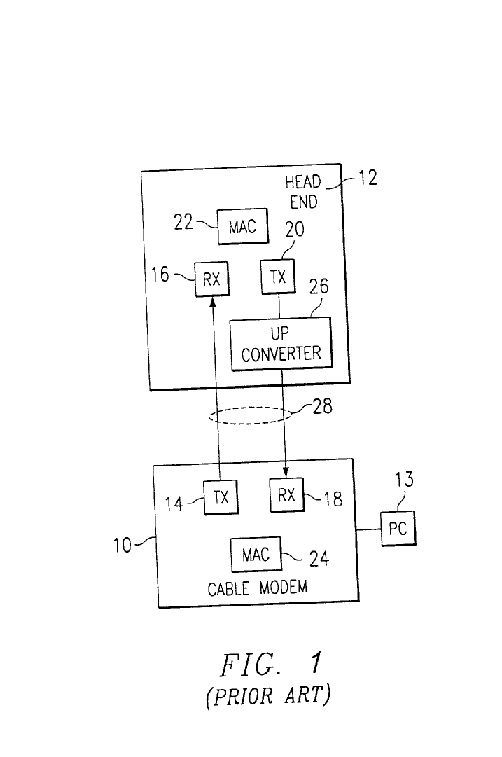

Corresponding numerals and symbols in the different figures and tables refer to corresponding parts unless otherwise indicated.

### DETAILED DESCRIPTION OF EMBODIMENTS OF THE INVENTION

Although the present invention finds particular application to the upstream channel in a DOCSIS system, which is described herein as an example, the invention is applicable to a wide range of communications system beyond DOCSIS upstream. For example, the invention could also be applicable to DOCSIS downstream networks and other networks that currently or in the future interface with HN networks. Moreover, the synchronized managed network disclosed herein would of benefit when used with any type of HN that communicates with other networks and devices. In addition, the word “transmission” is used broadly herein to include either transmitting data, receiving data or both. Various forms of the word “connect” as used herein represent both direct and indirect connection.

An integrated system combining DOCSIS cable access with 802.11e or Bluetooth WHN that preserves the high QoS features of the cable network all the way from the CMTS to the end-user's terminal is disclosed herein as an embodiment of the present invention. The present invention allows distribution of multiple data, voice, video, and multimedia streams inside the home in an efficient manner without degrading Quality of Service (QoS).

Quality of Service (QoS) is measured by the ability of the network to pass data streams from end to end at low worst-case delays and a low packet loss rate. The challenge of the network protocol designer is to achieve high QoS without degrading the network utilization, particularly in the presence of time varying demand peaks. The Home Network preferably needs to ensure that latency sensitive services such as voice and video conferencing receive guaranteed bandwidth, with bounded jitter and latency. Such low-latency data preferably receives priority over other data such as Internet, file transfer, etc.

It is anticipated that there will be multiple solutions in the HN market. Currently, various technologies exist today for HN. These classes of HN technologies include new wiring technologies, powerline, phone line and wireless. Wireless HN, currently appears to be the most favorable solution for the cable industry due to its “no wires”, QoS and cost advantages.

Currently, the new wiring class can be divided into Ethernet and IEEE1394b networks, which are based on CAT5 wiring infrastructure. Ethernet technology, which is the de-facto networking technology in business applications, offers 100 Mbps at a low cost. The 1394b technology is not as mature as the Ethernet technology, but it offers data rates of up to 400 Mbps and better QoS based on isochronous managed network. It can leverage the existing FireWire benefits (e.g. in content security) and applications. However, the vast majority of homes do not have CAT5 wiring today. Ethernet and 1394b networks will probably be found among new buildings, highly sophisticated users, and home offices, but overall their market share will be relatively small.

A new specification for powerline HN is currently being developed by the HomePlug industry alliance, with a current goal of 10 Mbps effective data rates. Given that power outlets are located in every room, and that most connected devices are already connected to them, powerline HN offers pretty good coverage of the home. Powerline HN is currently not suited to connect battery operated portable devices such as PDAs and cellphones. Moreover, powerline solutions will probably be relatively late to market, and their success depends on how well they will handle the power line channel, which is notorious for its high level of distortions and noise.

Two specifications have been developed by the Home Networking Phone Alliance (HPNA): HPNA 1.0 and HPNA 2.0, offering data rates of 1 Mbps and 10 Mbps respectively, using a prioritized Carrier Sense Multiple Access (CSMA) protocol. Most of the television sets, set-top boxes, and entertainment devices in the United States are not connected to the phone network and are quite remote from any phone jack. The need to pull a phone line to the “spaghetti” of wires in the back of a TV seems to be a significant drawback of HPNA solutions with respect to the needs of the cable industry.

Beyond its advantage of “no need for wires”, some current wireless solutions also allow good QoS and low cost. This class can generally be divided to three sub-classes: low data rate, 10 Mbps rate, and high end.

Low data rate (less than 2 Mbps): This subclass is currently led by Bluetooth solutions, operating in the 2.4 GHz RF band. Bluetooth offers raw data rates of 1 Mbps, and a managed network protocol that enables high QoS for voice and audio. Bluetooth, which was originally indented as a cable replacement technology (Personal Area Network) with a range of 10 meters, is also being suggested as a HN technology with a range of 100 meters. Its data rate may limit its use as the primary HN technology in the home. However, it is well suited to compliment other HN technologies by delivering certain data streams such as voice and audio because Bluetooth will probably be very popular in portable devices such as cell-phones, PDAs, Internet audio players, and notebook computers. The IEEE802.15 group has begun working on Bluetooth 2.0 spec with data rates of 10-20 Mbps.

10 Mbps rate: This subclass is currently led by IEEE802.11b solutions, also operating in the 2.4 GHz band. The 802.11b standard offers data rates of 11 Mbps. Its MAC is based on a CSMA protocol that offers low level of QoS. However, the 802.11b standard is migrating to the IEEE802.11e standard currently under specification which offers a high level of QoS based on managed network protocols. A strength of the IEEE802.11b approach lies in its unique “future compliant” behavior: Low QoS 802.11b terminals are designed to give priority to 802.11e terminals without degrading their QoS. The IEEE802.11 group is also working on the 802.11g standard which will extend 802.11b data rates to 20-40 Mbps.

High end: This subclass is currently led by IEEE802.11a solutions, operating in the 5 GHz band. The IEEE802.11a offer data rates of up to 52 Mbps and high QoS based on the 802.11e MAC protocols.

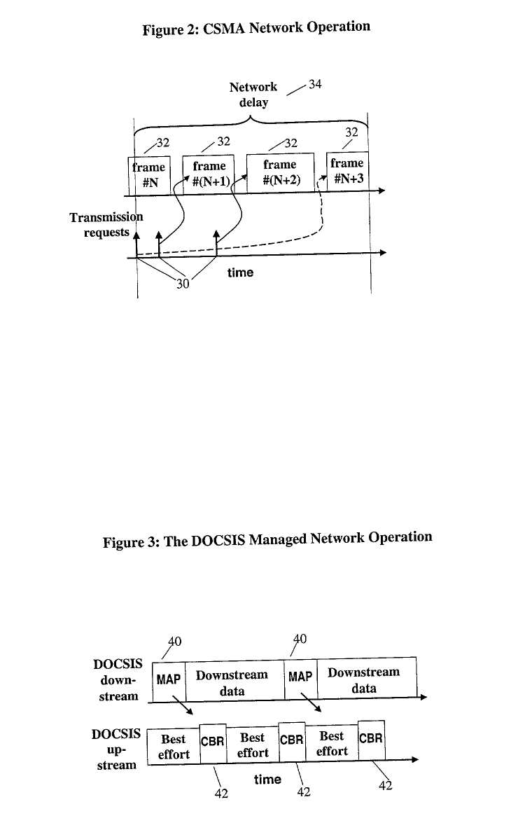

FIG. 2 shows, as an example, the operation of a Carrier Sense Multiple Access (CSMA) network, such as Ethernet and other networks that are using the IEEE802.3 MAC protocol. In such a network, stations 30 that want to transmit wait until the line is idle, and then compete for line access. One of stations eventually wins line access and transmits a data packet 32. Once this packet is transmitted and the line is idle again, all the other stations 30 that wanted to transmit (together with new ones that may want to transmit as well) compete again for the line. Obviously, CSMA networks may suffer from large worst case delays. In the example given in FIG. 2, the delay 34 between the access request and the actual transmission could reach as much as four packet periods due to the appearance of two access requests before the first request is satisfied. Prioritized CSMA protocols, such as HPNA 2.0, improve CSMA by making sure that high priority stations get priority over low priority stations when competing for line access. This may significantly improve the worst case delay of the network, yet the delays due to higher or equal priority stations may be high. In addition to that, there is a concern that some stations 30, due to bad implementation, will not adhere to standard practices when selecting their own priorities and will select for themselves higher priority levels than they actually need, thereby degrading the QoS of the network. This concern is particularly severe because the cable operators have limited control over the HN terminals.

FIG. 3 shows the operation of a managed network such as DOCSIS, IEEE1394, or IEEE802.11e. In such a network, there is a manager (e.g. the CMTS in the case of DOCSIS) that receives transmission requests from all the stations, and based on these requests allocates 40 time-slots 42 during which the stations can transmit. In the case of voice, audio or video streams, which are characterized by a relatively constant rate of packets, the manager can forecast the bandwidth needs of the applications thereby allocating 40 time slots 42 for them, in advance, with a very small delay.

The cable industry has invested significant efforts in ensuring that the DOCSIS 1.1 specification includes QoS capabilities that could guarantee the reliable performance of latency sensitive broadband services such as voice. However, concatenating home networks to DOCSIS may degrade its QoS since the overall delay is the sum of delays of all networks, which is typically dominated by the lowest QoS network in the link. With these services distributed into the home, the high level of QoS as defined in DOCSIS 1.1 needs to be maintained also throughout the home in order to ensure their reliable delivery into the home.

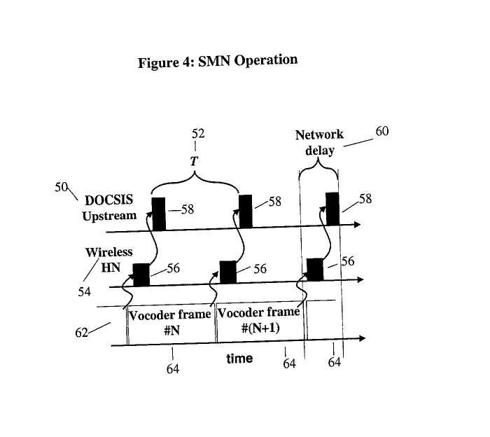

In order to maintain DOCSIS QoS all the way to the HN terminal an embodiment of the present invention provides Synchronized Managed Networking (SMN). SMN is a cascade of DOCSIS, for example, and managed home networks, such as Bluetooth or IEEE802.11e. The operation of SMN is demonstrated in FIG. 4 for the case of the DOCSIS upstream network.

The DOCSIS 50 manager allocates time slots for an upstream high QoS stream at a frame period T 52. The HN 54 manager, which is typically implemented at the cable gateway (e.g. a CM or a STB), learns the timing of the stream in the DOCSIS 50 network, and based on that, reserves timing slots for the stream in the HN. The learning of the stream timing may be done using messaging between the CMTS and the HN manager, and using the time-sync mechanism of the DOCSIS 50 MAC. The stream timing can also be learned passively without any special messaging, but that would typically be less efficient. The HN 54 transmission opportunities 56 are reserved for just a short period before the expected transmission opportunities 58 in the DOCSIS 50 network so that the overall delay 60 is minimized. This time preferably also accounts for networks jitter and implementation delay of the HN 52 receiver and the DOCSIS 50 transmitter. If there are multiple home networks cascaded to each other (e.g. a cascade of DOCSIS, 1394 and Bluetooth) each HN 54 can synchronize to the stream timing in the preceding network in the cascade. Multimedia processing is typically done frame by frame. For example, vocoders 62 have frame periods of 10-20 milliseconds. In the SMN example provided in FIG. 4, the vocoder 62 learns the stream timing, and finishes the processing of a frame a short time before the station expects a transmission opportunity 64. The synchronized time periods in the present invention may or may not overlap.

As shown in FIG. 4, the overall delay 60 of the network consists of the sum of:

“air times” 56, 58 of the HN 54 and the DOCSIS 50 network—that is the size of the frame [bits] divided by the network data rate [bits per second];

networks' delay jitter—which is generally small when the networks are managed;

processing delays—required by the stations to transmit or receive the data which can be kept small if the software tasks that handle the data are high priority tasks; and

propagation delays (significant only in DOCSIS where it may reach up to 100 microseconds).

SMNs allow concatenating, for example, DOCSIS with a cascade of HN's with a very small degradation to DOCSIS QoS. On the other hand, a cascade of DOCSIS with non-synchronized home networks may result in a large worst case delay. In the example of FIG. 4, the worst case delay could reach 3T plus the sum of network delay jitters (which could be quite significant in non-managed networks), processing delays, and propagation delays.

The present invention may also be practiced in the downstream direction by implementing, for example, a SMN as described above that synchronizes the downstream allocated time with the HN transmission and the transmission for the decoder or other device communicating with the HN.

In order to distribute reliably and consistently latency sensitive applications such as voice and video, Home Networks preferably will be a managed network that is coordinated and synchronized with the DOCSIS network. Currently, the emerging 802.11e standard is probably best positioned to become the backbone of such a network. Its QoS service capabilities coupled with its competitive cost, and its inherent advantage of complete home coverage with no wires at all, make it a good candidate for the HN technology of choice for delivering cable broadband services. That said, the Home Network will probably be a heterogeneous environment in which multiple HN technologies will co-exist. In addition, wired HN technologies such as HPNA and power line will probably ultimately adopt QoS functionality which will make them better suited for the distribution of cable broadband services into the home. The present invention disclosed herein, will enable provision of improved broadband service to the home with varied HN technologies particularly as HN standard, such as HPNA, evolve and addition and improve upon managed network and QoS functionality.

Thus, a system and method are provided, as an example, that preserves the high QoS features of the cable network all the way from the CMTS to the end-user's terminal. The present invention allows distribution of multiple data, voice, video, and multimedia streams inside the home in an efficient manner without degrading QoS.

While the invention has been described with reference to illustrative embodiments, this description is not intended to be construed in a limiting sense. Various other embodiments of the invention will be apparent to persons skilled in the art upon reference to this description. For example, the invention could also be applicable to DOCSIS downstream networks and other networks that currently or in the future interface with HN networks. In addition, the synchronized managed network disclosed herein would of benefit when used with any type of HN that communicates with other networks and devices.

It is therefore contemplated that the appended claims will cover any such modifications of the embodiments as fall within the true scope and spirit of the invention.

What is claimed is:

1. A data communication system comprising:
a first manager for allocating a first time slot to a first network; and
a second manager for allocating a second time slot to a second network such that one of the first time slot or the second time slot begins a short time before the other of the first time slot or the second time slot begins wherein data is transmitted between the second network and the first network during the first time slot or the second time slot.

2. The system of claim 1, wherein the first network or the second network is a cable network.

3. The system of claim 1, wherein the first network or the second network is a home network.

4, The system of claim 1, wherein the first network and the second network are home networks.

5. The system of claim 1, wherein the first time slot and the second time slot do not overlap.

6. The system of claim 1, wherein the second time slot begins a short time before the first time slot begins.

7. The system of claim 6, wherein one or more devices is connected to the second network.

8, The system of claim 7, wherein one or more of the devices begin transmitting data to the second network a short time before the second time slot begins.

9. The system of claim 1, wherein the first time slot begins a short time before the second time slot begins.

10. The system of claim 9, wherein one or more devices is connected to the first network.

11. The system of claim 10, wherein one or more of the devices begin transmitting data to the first network a short time before the first time slot begins.

12. A method for the transmission of data comprising:
allocating a first time slot to a first network; and
allocating a second time slot to a second network such that one of the first time slot or the second time slot begins a short time before the other of the first time slot or the second time slot begins wherein data is transmitted between the second network and the first network during the first time slot or the second time slot.

13. The method of claim 12, wherein the first network or the second network is a cable network.

14. The method of claim 12 wherein the first network or the second network is a home network.

15. The method of claim 12, wherein the first network and the second network are home networks.

16. The method of claim 12, wherein the first time slot and the second time slot do not overlap.

17. The method of claim 12, wherein the second time slot begins a short time before the first time slot begins.

18. The method of claim 17, further comprising allocating a third time slot to one or more devices connected to the second network for transmitting data from one or more of the devices to the second network such that the third time slot begins a short time before the second time slot begins.

19. The method of claim 12, wherein the first time slot begins a short time before the second time slot begins.

20. The method of claim 19, further comprising allocating a third time slot to one or more devices connected to the first network for transmitting data from one or more of the devices to the first network such that the third time slot begins a short time before the first time slot begins.

21. A multi-network data communication system having a cable network and a home network, said system comprising:
a first manager for allocating a first time slot to the cable network for transmission of data; and
a second manager for allocating a second time slot to the home network for transmission of data from the home network to the cable network such that the second time slot is a short time before the first time slot.

22. A method for synchronizing a cable network and a home network comprising:
allocating a first time slot to the cable network for transmission of data; and
allocating a second time slot to the home network for transmission of data from the home network to the cable network such that the second time slot is a short time before the first time slot.
